(19) United States
(12) Patent Application Publication
(10) Pub. No.: US 2019/0088847 A1
(43) Pub. Date: Mar. 21, 2019

(54) DISTRIBUTED THERMOELECTRICS WITH NON-UNIFORM THERMAL TRANSFER CHARACTERISTICS

(71) Applicant: Gentherm Incorporated, Northville, MI (US)

(72) Inventor: Rüdiger Spillner, Augsburg (DE)

(21) Appl. No.: 16/082,469

(22) PCT Filed: Mar. 22, 2017
(86) PCT No.: PCT/US2017/023530

§ 371 Date: Sep. 5, 2018

Related U.S. Application Data
(60) Provisional application No. 62/311,467, filed on Mar. 22, 2016.

(51) Int. Cl. H01L 35/32; H01L 35/30

(52) U.S. Cl. CPC H01L 35/32; F25B 21/02; H01L 35/30

(57) ABSTRACT

A thermoelectric assembly includes a thermoelectric device that has varying distribution of p-n pellets in an in-plane direction that is configured to provide non-uniform thermal conditioning. The thermoelectric device includes a first set of p-n pellets arranged in a first packing density in a first area. A second set of p-n pellets is arranged in a second packing density in a second area that is a different packing density than the first packing density.

### CROSS-REFERENCE TO RELATED APPLICATIONS

This application claims priority to U.S. Provisional Application No. 62/311,467, which was filed on Mar. 22, 2016 and is incorporated herein by reference.

### BACKGROUND

This disclosure relates to conductive cooling of surfaces, such as seat covers, battery thermal management, or electronics, for example, using distributed thermoelectrics.

Heated and cooled seats are becoming more prevalent in automotive applications. One approach is to use a flexible duct mounted to a shaped foam block that forms a seat cushion or seat back. Conditioned air is blown through the duct. A fabric is supported on the flexible duct, and a perforated aesthetic cover is wrapped around the foam. Air is supplied through apertures in the flexible duct and then passed through perforations in the cover to thermally regulate the seating surface. Covers with perforations may be undesirable. Additionally, there are thermal losses with the above approach.

Another approach to thermally conditioning a seat uses a single, large thermoelectric device (TED) with equally spaced p-n pellets, which provides a uniform pellet packing density in the in-plane direction. This may result in an increased number of pellets or overall lower power density than desired for portions of the seating surface. If more than a needed amount of pellets is used for the application, unnecessary electrical connections are used, part count is increased, and a more complex than needed assembly is provided. The unintended consequences of a TED with uniform pellet packing density may be reduced reliability, increased cost and reduced efficiency.

### SUMMARY

In one exemplary embodiment, a thermoelectric assembly includes a thermoelectric device that has varying distribution of p-n pellets in an in-plane direction that is configured to provide non-uniform thermal conditioning. The thermoelectric device includes a first set of p-n pellets arranged in a first packing density in a first area. A second set of p-n pellets is arranged in a second packing density in a second area that is a different packing density than the first packing density.

In a further embodiment of any of the above, the first and second sets of p-n pellets are electrically connected to one another with shunts in the same circuit on a common substrate.

In a further embodiment of any of the above, the circuit includes at least some p-n pellets electrically connected to one another in series.

In a further embodiment of any of the above, the circuit includes at least some p-n pellets electrically connected to one another in parallel.

In a further embodiment of any of the above, the thermoelectric device includes an insulation layer between the shunts and the substrate in a through-plane direction.

In a further embodiment of any of the above, the thermoelectric device includes an insulation layer between the shunts in the in-plane direction.

In a further embodiment of any of the above, insulation layer provides the substrate.

In a further embodiment of any of the above, the substrate is arranged between p-n pellets in the in-plane direction.

In a further embodiment of any of the above, the shunts are arranged between the p-n pellets in the in-plane direction.

In a further embodiment of any of the above, at least the substrate is flexible and configured to permit the p-n pellets to move relative to one another in a through-plane direction.

In a further embodiment of any of the above, the thermoelectric device includes a spacer that extends in a through-plane direction and has a rigidity that is equal to or greater than a pellet rigidity of the p-n pellets. The spacer is configured to prevent an undesired pellet compression condition.

In a further embodiment of any of the above, the shunts are arranged in a predefined grid. The first and second sets of p-n pellets are arranged on the predefined grid.

In a further embodiment of any of the above, the shunts include a common length. The common length shunts electrically connect the first and second sets of p-n pellets to one another.

In a further embodiment of any of the above, the shunts include a different length from one another. The different length shunts electrically connect the first and second sets of p-n pellets to one another.

In a further embodiment of any of the above, the shunts include main and waste side shunts. An aesthetic cover is arranged adjacent to the main side shunt. A fluid passage is arranged adjacent to the waste side shunt. A blower is in fluid communication with the fluid passage and is configured to blow a fluid through the fluid passage to provide heat flux between the fluid and the waste side shunt. The thermoelectric device is configured to provide non-uniform thermal conditioning of the aesthetic cover.

In another exemplary embodiment, a method of designing a thermoelectric assembly includes the step of modeling a thermodynamic system which includes a modeled temperature distribution on a surface from an object. A modeled heat flux from the surface through a modeled thermoelectric assembly that has p-n pellets to an environment is includes. A thermoelectric assembly is built based upon the modeled temperature distribution, modeled heat flux, and modeled thermoelectric assembly to provide a first packing density of p-n pellets in a first area. A second packing density of p-n pellets in a second area is provided that is a different packing density than the first packing density to provide a varying distribution of p-n pellets in an in-plane direction that is configured to provide non-uniform thermal conditioning.

In a further embodiment of any of the above, the modeling step includes a modeled pressure distribution on the modeled thermoelectric assembly. The first and second densities are based upon the modeled pressure distribution to prevent an undesired load on the p-n pellets.

In a further embodiment of any of the above, the modeling step includes determining the shortest electrical connections between the p-n pellets.

In a further embodiment of any of the above, the modeling step includes determining series and parallel electrical connections between the p-n pellets.

In a further embodiment of any of the above, the thermoelectric assembly is built to position the first and second densities to equalize at least one of the modeled temperature distribution and the modeled heat flux across the surface.

### BRIEF DESCRIPTION OF THE DRAWINGS

The disclosure can be further understood by reference to the following detailed description when considered in connection with the accompanying drawings wherein:

FIG. 1 is a schematic view of a thermodynamic system.

FIG. 2 is an exploded view of a thermoelectric device and example adjacent layers.

FIG. 3 is a plan view of a portion of an example thermoelectric device with a distributed architecture.

FIG. 4A is an in-plane sectional view of the thermoelectric device through p-n pellets.

FIG. 4B is a top elevational view of the thermoelectric device shown in FIG. 4A.

FIG. 4C is a bottom elevational view of the thermoelectric device shown in FIG. 4A.

FIG. 5 is one example thermoelectric device component configuration.

FIG. 6 is another example thermoelectric device component configuration.

FIG. 7 is still another example thermoelectric device component configuration.

FIG. 8 is yet another example thermoelectric device component configuration.

FIG. 9 is another example thermoelectric device component configuration.

FIG. 10 is still another example thermoelectric device component configuration.

FIG. 11 is yet another example thermoelectric device component configuration.

FIG. 12A is a schematic view of an example thermoelectric device with p-n pellets having a varying in-plane packing density and different length electrical connections between the pellets.

FIG. 12B is a top elevational view of the thermoelectric device shown in FIG. 12A.

FIG. 12C is a bottom elevational view of the thermoelectric device shown in FIG. 12A.

FIG. 13 is a schematic view of an example thermoelectric device with p-n pellets having a varying in-plane packing density and same length electrical connections between the pellets.

FIG. 14 is a schematic view of the thermoelectric device shown in FIG. 13 with spacers to limit undesired compression of the thermoelectric device.

FIG. 15 is a schematic view of an example thermoelectric device with predefined grid that provides electrical connections to the p-n pellets.

FIG. 16 is a schematic view of an example thermoelectric device with series and parallel electrical connections between pellets of varying size.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### DETAILED DESCRIPTION

A thermodynamic system 10 is shown in a highly schematic manner in FIG. 1. A thermoelectric device (TED) 12 is arranged between main and waste side interfaces 18, 20. The main side interface 18 directly or indirectly supports an object 14 on a surface 22, and the waste side interface is adjacent to an environment 16. The object 14 may be electronics, a battery, a seated occupant, or an environment, for example. When electrical power is applied to the TED 12, the TED 12 acts as a heat pump to generate a heat flux that flows from the object 14 to the environment 16 to cool the object 14, for example. In another embodiment, the thermoelectric device 12 can be oriented differently to reverse the heat flux direction and heat, instead of cool, the object 14. In another embodiment, the TED 12 can be configured as a passive arrangement in which a through-plane heat flux induces a current in the TED 12 to generate electrical power.

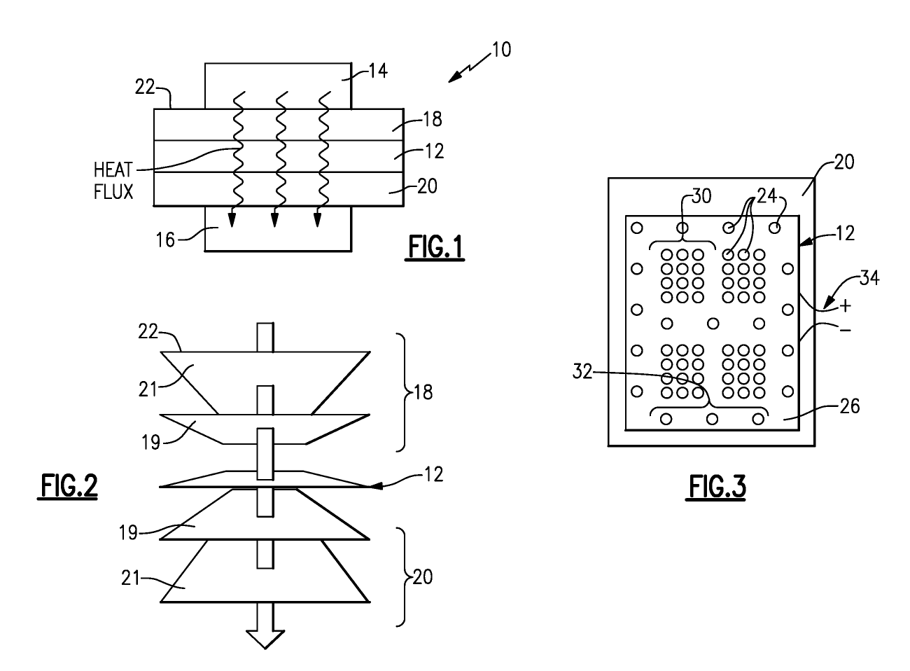

One or both of the main and waste side interfaces 18, 20 may include one or more layers. In one example shown in FIG. 2, the main and/or waste side interfaces 18, 20 include a joint layer 19 and a heat exchanger layer 21, although these layers may be omitted if desired. The joint layer 19 may be at least one of a thermal pad, glue, solder, thermal paste and/or foil, which is used to secure the TED 12 to the heat exchanger layer 21, if used. The heat exchanger layer 21 may be at least one of a heat spreader, heat exchanger, fins, chassis, housing, duct and/or fluid, such as coolant, waste gas, air or plasma. The layers 19, 21 can be used to create or stop heat transfer and/or sense heat transfer via a sensed temperature and/or temperature difference.

A typical TED has an equal spacing of p-n pellets, which provides a uniform pellet packing density in the in-plane direction. The p-n pellets generate a heat flux when electrical power is applied by a power source. Rather than providing multiple discrete “off the shelf” TEDs in the thermoelectric system 10, at least one large TED 12 having a varying p-n pellet distribution in an in-plane direction is provided based upon the application by taking into account the variables affecting each element of the TED 12 using a disclosed design process. For example, as shown in FIG. 3, the TED 12 includes a first set 30 of p-n pellets 24 arranged in a first packing density in a first area, and a second set 32 of p-n pellets 24 arranged in a second packing density in a second area that is a different packing density than the first packing density. Of course, the two areas shown are exemplary and more area and/or differently configured areas may also be used. Moreover, separated areas with identical pellet packing density are also contemplated by the disclosed first and second packing densities. So, the heat flux of any given system can be modelled to determine the desired p-n pellet arrangement in the same circuit 34 on a common substrate 26 using various design constraints.

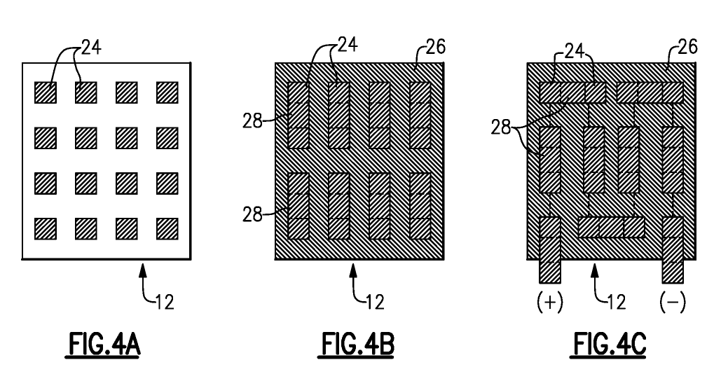

FIGS. 4A-4C illustrate one type of TED construction. The p-n pellets 24 extend in the through-plane direction between substrates 26. Shunts 28 are provided on the main side (e.g., FIG. 4B) and the waste side (e.g., FIG. 4C) to electrically connect the p-n pellets 28 in a circuit. The p-n pellets 24 are shown as being uniformly distributed in FIGS. 4A-4C for simplicity, although the disclosed TED 12 has at least a portion of the p-n pellets distributed unevenly, as shown in FIGS. 3 and 12A-16.

In the example of a seating application, the shunts include main and waste side shunts, where an aesthetic cover is arranged adjacent to the main side shunt. A fluid passage is arranged adjacent to the waste side shunt, and a blower in fluid communication with the fluid passage and configured to blow a fluid through the fluid passage to provide heat flux between the fluid and the waste side shunt. The disclosed TED is configured to provide non-uniform thermal conditioning of the aesthetic cover.

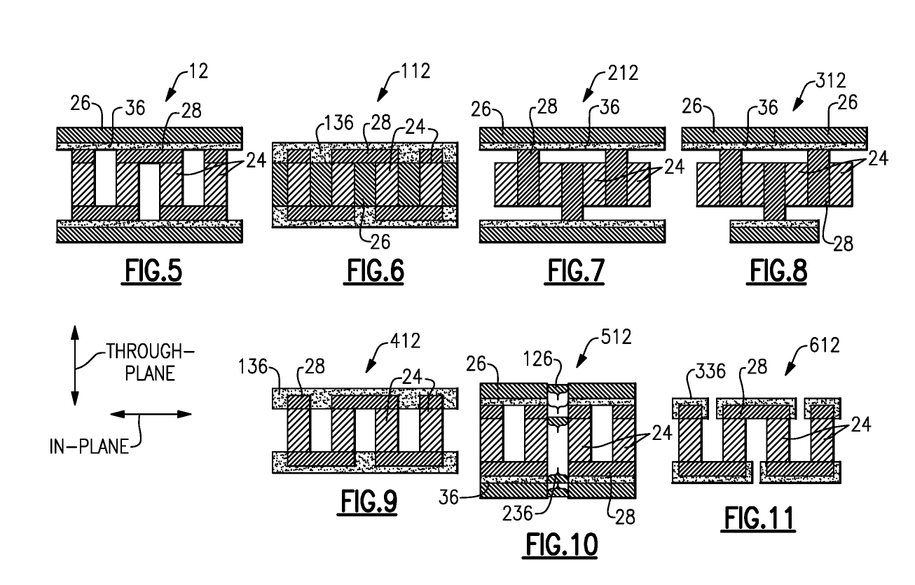

The disclosed TED may be constructed using a variety of configurations depending upon the application and the desired performance and functionality. Some example constructions are shown in FIGS. 5-11. Referring to FIG. 5, an electrical insulation layer 36 is arranged adjacent to the shunts 28 and is supported by the substrate 26 in the through-plane direction. In the example shown in FIG. 6, the TED 112 incorporates the insulation layer 136 adjacent to the shunts 28, and the substrate 26 is provided between the p-n pellets 24 in the in-plane direction. In the example TEDs 212, 312 shown in FIGS. 7 and 8, the shunts 28 are arranged between the p-n pellets 24 in the in-plane direction. The substrate 26 can be discrete and insulated from one another, as shown in FIG. 8.

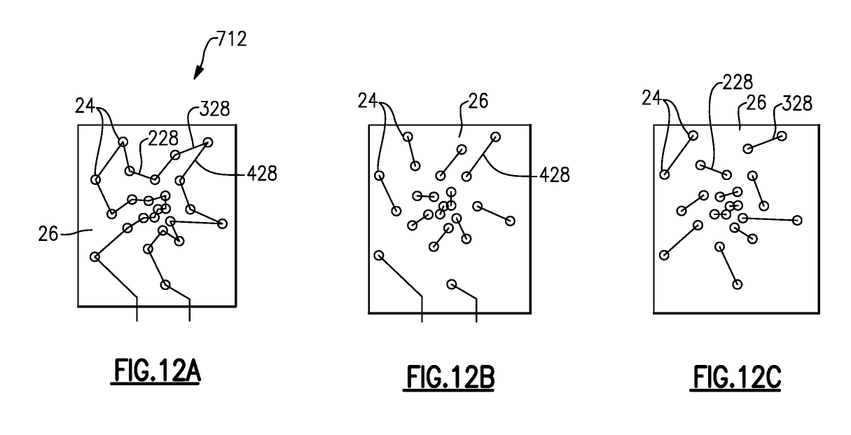

Referring to the TED 412 shown in FIG. 9, the insulation layer 136 may also provide the substrate and may be arranged between the shunts 28 in the in-plane direction, as also shown in FIG. 6. A flexible TED 512 may be provided, as shown in FIG. 10, using at least one of a flexible substrate 126, shunt 128 and insulation layer 236, which permits the p-n pellets 24 to move relative to one another in a through-plane direction. Referring to FIG. 11, the insulation layer 336 covers the shunts 28 in the in-plane and through-plane directions without a substrate, which provides a more flexible TED 612.

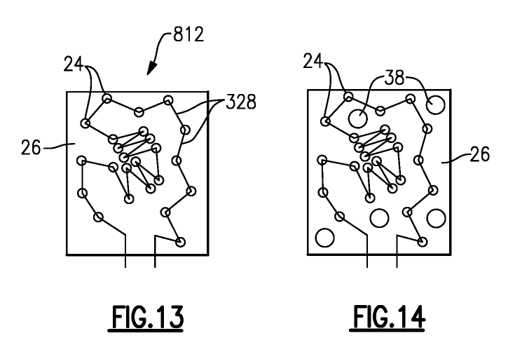

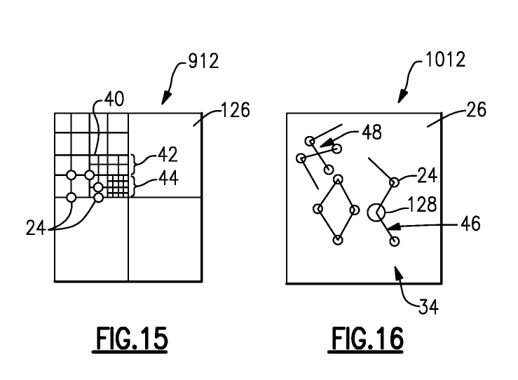

Since adjacent p-n pellets are arranged at different, irregular distances from one another to place the p-n pellets in a more optimal position for the particular application, unlike typical TEDs, electrically connecting the p-n pellets may be more challenging. One approach, depicted in FIGS. 12A-12C, uses shunts 228, 328, 428 of various lengths based upon the desired position of the p-n pellets 24 for the TED 712. Manufacturing processes such as metal depositing, printing, etching, or milling, for example, may alleviate the difficulty of using numerous shunt lengths in assembly and also accommodate different shaped shunts that may be desired for use around cutouts or screws. Because using distributed pellets could undesirably require a larger number of shunt lengths, a common shunt length may be used to connect the p-n pellets 24, which may necessitate the p-n pellets to be moved slightly from their desired position for the TED 812 to accommodate the same shunts 328 for the various electrical connections, as shown in FIG. 13. A stock of several fixed length shunts may be selected from to make the connections. Because the p-n pellet in-plane spacing may be different, the perimeter of the TED may be more easily be made any shape and customized based upon a resultant irregularly shaped outermost perimeter of p-n pellets rather than the typical orthogonal TED perimeter.

Referring to FIG. 14, the TED includes a spacer 38 extending in the through-plane direction and having a rigidity that is significantly greater than a pellet rigidity, or Young's modulus, of the p-n pellets 24. The spacer 38 is configured to prevent an undesired pellet compression condition resulting from a mechanical overload of the TED. Active and/or passive electronics such as resistors, amplifiers, sensors, and/or LEDs may be integrated into the TED.

Another approach to providing the electrical connections between p-n pellets 24 is to provide a predefined grid 40 of shunts, for example, first and second grid spacings 42, 44 (e.g., orthogonal), which provide different possible connection locations within the TED 912. The same predefined grid 40 may provide enough variability such that the grids may be used to design different TEDs with different arrangements of p-n pellets.

As shown in FIG. 16, the circuit 34 may include at least some p-n pellets 24 electrically connected to one another in series 46 and/or in parallel 48. Connecting the pellets in parallel reduces the likelihood of a total failure and can be used to reduce the TED's electrical resistance or set specific voltage/current range, which influences the effect and the efficiency.

Different size p-n pellets 128 may also be used in the TED 1012. The size of the pellet effects the electrical and thermal resistance of pellet, influences efficiency and other thermoelectric features.

The above TED configurations provide construction techniques that may be used to build a TED with a variable in-plane distribution of p-n pellets to achieve a non-uniform, targeted thermal boundary condition matched to the given application. The disclosed thermoelectric assembly can be designed by a method that takes into consideration a variety of design factors and system characteristics.

Target system characteristics are identified or defined and their planar or spatial distribution on the surface 22 (FIG. 1) is determined, e.g., temperature and heat flux on a battery housing. The target system characteristics and their planar or spatial distribution on at least the environment 16 (FIG. 1) is determined, e.g., temperature of coolant water along flow direction in an heat exchanger. Conditions of the interfaces between the various components of the system stack (FIGS. 1 and 2) are determined, e.g., pressure distribution on a thermal mat, resulting in a non-uniform thermal conductivity.

A design method for constructing a thermoelectric assembly includes modeling a thermodynamic system that has a modeled temperature distribution on a surface from an object, and a modeled heat flux or temperature from the surface through a modeled thermoelectric assembly having p-n pellets to an environment. The heat flux or temperature of the system may be modeled in x, y, z coordinates in a finite elements model, taking into account thermal conductivity of the materials, heat transfer coefficients and other system characteristics. The Peltier effect provided by the p-n pellets, thermal resistance, parasitic losses and other TED characteristics may also be considered. The modeling step may include a modeled pressure distribution on the modeled thermoelectric assembly, where the first and second packing densities are based upon the modeled pressure distribution to prevent an undesired load on the p-n pellets.

A solution of pellet distribution and the path of their interconnection is determined that satisfies defined optimization criteria, ranging from a one step heuristic solution up to a recursive transient simulation. The thermoelectric assembly is built based upon the modeled temperature distribution, modeled heat flux, and modeled thermoelectric assembly to provide the first packing density of p-n pellets in the first area, and the second packing density of p-n pellets in the second area that is a different density than the first packing density, which provides a varying distribution of p-n pellets in an in-plane direction that is configured to provide non-uniform thermal conditioning on the pellet/TED; however, thermal conditioning at the target (e.g., between the surface and object) may be non-uniform or uniform by design. For example, the thermoelectric assembly can be built to position the first and second packing densities to equalize at least one of the modeled temperature distribution and the modeled heat flux across the surface or portions of the surface.

The characteristics of these steps are matched according to their planar or spatial distribution, yielding a per point (area, volume) resolution of heat transfer boundary conditions or requirements. The boundary conditions and limitations are provided for optimization based upon various goals, e.g., maximum coefficient of performance (COP), area available, spots for current in/out, minimum pellet-to-pellet distance. Other factors may include determining the shortest electrical connections between the p-n pellets, or determining series and parallel electrical connections between the p-n pellets.

The design criteria and the solution can include several, different, even contradicting goals, multidimensional or fuzzy variables and can allow several local optima. Optimization and approximation algorithms together with weight matrixes can be used to to design the TED for the application. Optimizing the interconnections towards lowest resistivity to avoid parasitic losses, for example, can be used for any given pellet distribution, using a traveling salesman algorithm to determine the shortest distance to make the needed electrical connections. The process can be iterative and recursive and consider steady state and transient conditions. For example, a steady state interaction of a preliminarily chosen p-n pellet distribution in an specific application setup can be simulated using finite element methods, whose results are fed back to the placement algorithm, defining a new, more precise or improved placement, which is fed back to the finite element method and so on.

The process can include heuristic algorithms and approximations. For example a rule of thumb could be, that for a given temperature difference (derived from match data in a steady state), a proportional number of pellets per area has to be placed. In calculating the placements of thermoelectric p-n pellets, different areas can be treated individually. Pellets can be placed as single pellets or in groups. An example approach to simplify the solution is to define pellet packing density per area of interest according to the respective data (matched characteristics) and then connect the pellets in a local regular pattern. Examples for possible design optimization criteria include without exclusion: maximum or optimal COP for the TED, maximum heat transfer for a given number of p-n pellets, relatively equal temperature distribution on a medium, relatively equal heatflux through defined area, lowest TED cost (introducing cost function to design parameters), and/or minimal packing density of pellet distribution for a given mechanical load.

A TED designed according to the disclosed method reduces the number of p-n pellets to better match its application, which results in increased efficiency and reduced weight and cost, by placing a greater number of p-n pellets in the optimal thermal boundary condition for operation. With improved efficiency one or more heat spreader layers may be eliminated, which reduces the overall height of the TED. The number and length of the shunts may also be reduced, which minimizes parasitic losses and improves reliability and voltage range. Assembly is also simplified, and the shape of the TED can better customized.

It should also be understood that although a particular component arrangement is disclosed in the illustrated embodiment, other arrangements will benefit herefrom. Although particular step sequences are shown, described, and claimed, it should be understood that steps may be performed in any order, separated or combined unless otherwise indicated and will still benefit from the present invention.

Although the different examples have specific components shown in the illustrations, embodiments of this invention are not limited to those particular combinations. It is possible to use some of the components or features from one of the examples in combination with features or components from another one of the examples.

Although an example embodiment has been disclosed, a worker of ordinary skill in this art would recognize that certain modifications would come within the scope of the claims. For that reason, the following claims should be studied to determine their true scope and content.

What is claimed is:

1. A thermoelectric assembly comprising:
a thermoelectric device having varying distribution of p-n pellets in an in-plane direction that is configured to provide non-uniform thermal conditioning, wherein the thermoelectric device includes a first set of p-n pellets arranged in a first packing density in a first area, and a second set of p-n pellets arranged in a second packing density in a second area that is a different packing density than the first packing density.

2. The thermoelectric assembly according to claim 1, wherein the first and second sets of p-n pellets are electrically connected to one another with shunts in the same circuit on a common substrate.

3. The thermoelectric assembly according to claim 2, wherein the circuit includes at least some p-n pellets electrically connected to one another in series.

4. The thermoelectric assembly according to claim 3, wherein the circuit includes at least some p-n pellets electrically connected to one another in parallel.

5. The thermoelectric assembly according to claim 2, wherein the thermoelectric device includes an insulation layer between the shunts and the substrate in a through-plane direction.

6. The thermoelectric assembly according to claim 2, wherein the thermoelectric device includes an insulation layer between the shunts in the in-plane direction.

7. The thermoelectric assembly according to claim 6, wherein insulation layer provides the substrate.

8. The thermoelectric assembly according to claim 6, wherein the substrate is arranged between p-n pellets in the in-plane direction.

9. The thermoelectric assembly according to claim 2, wherein the shunts are arranged between the p-n pellets in the in-plane direction.

10. The thermoelectric assembly according to claim 2, wherein at least the substrate is flexible and configured to permit the p-n pellets to move relative to one another in a through-plane direction.

11. The thermoelectric assembly according to claim 2, wherein the thermoelectric device includes a spacer extending in a through-plane direction and having a rigidity that is equal to or greater than a pellet rigidity of the p-n pellets, the spacer configured to prevent an undesired pellet compression condition.

12. The thermoelectric assembly according to claim 2, wherein the shunts are arranged in a predefined grid, and the first and second sets of p-n pellets are arranged on the predefined grid.

13. The thermoelectric assembly according to claim 2, wherein the shunts include a common length, the common length shunts electrically connecting the first and second sets of p-n pellets to one another.

14. The thermoelectric assembly according to claim 2, wherein the shunts include a different length from one another, the different length shunts electrically connecting the first and second sets of p-n pellets to one another.

15. The thermoelectric assembly according to claim 2, wherein the shunts include main and waste side shunts, and comprising an aesthetic cover arranged adjacent to the main side shunt, and a fluid passage arranged adjacent to the waste side shunt, and a blower in fluid communication with the fluid passage and configured to blow a fluid through the fluid passage to provide heat flux between the fluid and the waste side shunt, wherein the thermoelectric device is configured to provide non-uniform thermal conditioning of the aesthetic cover.

16. A method of designing a thermoelectric assembly comprising the steps of:
modeling a thermodynamic system including:
a modeled temperature distribution on a surface from an object;
a modeled heat flux from the surface through a modeled thermoelectric assembly having p-n pellets to an environment;
building a thermoelectric assembly based upon the modeled temperature distribution, modeled heat flux, and modeled thermoelectric assembly to provide a first packing density of p-n pellets in a first area, and a second packing density of p-n pellets in a second area that is a different packing density than the first packing density to provide a varying distribution of p-n pellets in an in-plane direction that is configured to provide non-uniform thermal conditioning.

17. The method according to claim 16, wherein the modeling step includes a modeled pressure distribution on the modeled thermoelectric assembly, and the first and second densities are based upon the modeled pressure distribution to prevent an undesired load on the p-n pellets.

18. The method according to claim 16, wherein the modeling step includes determining the shortest electrical connections between the p-n pellets.

19. The method according to claim 16, wherein the modeling step includes determining series and parallel electrical connections between the p-n pellets.

20. The method according to claim 16, wherein the thermoelectric assembly is built to position the first and second densities to equalize at least one of the modeled temperature distribution and the modeled heat flux across the surface.
